(19) United States
(12) Patent Application Publication
(10) Pub. No.: US 2013/0334670 A1
(43) Pub. Date: Dec. 19, 2013

(54) SEMICONDUCTOR DEVICE AND FABRICATION METHOD THEREOF

(71) Applicant: SK HYNIX INC., Gyeonggi-do (KR)

(72) Inventors: Seung Beom BAEK, Gyeonggi-do (KR); Su Jin CHAE, Gyeonggi-do (KR); Min Yong LEE, Gyeonggi-do (KR); Hye Jin SEO, Gyeonggi-do (KR); Young Ho LEE, Gyeonggi-do (KR); Jin Ku LEE, Gyeonggi-do (KR); Jong Chul LEE, Gyeonggi-do (KR)

(73) Assignee: SK HYNIX INC., Gyeonggi-do (KR)

(21) Appl. No.: 13/716,011

(22) Filed: Dec. 14, 2012

(30) Foreign Application Priority Data
Jun. 19, 2012 (KR) 10-2012-0065801

(51) Int. Cl. H01L 29/868; H01L 21/02

(52) U.S. Cl. CPC H01L 29/868; H01L 21/02518
USPC 257/656; 438/478

(57) ABSTRACT

A semiconductor device and a fabrication method thereof are provided. The semiconductor device includes a first type semiconductor layer doped with an N type ion, a second type semiconductor layer formed over the first type semiconductor layer, and a silicon germanium (SiGe) layer doped with a P type ion formed over the second type semiconductor layer.

### CROSS-REFERENCES TO RELATED APPLICATION

This application claims priority under 35 U.S.C. 119(a) to Korean application number 10-2012-0065801, filed on Jun. 19, 2012, in the Korean Patent Office, which is incorporated by reference in its entirety.

### BACKGROUND OF THE INVENTION

1. Technical Field

The embodiments of the present invention relate to a semiconductor device, and more particularly, to a semiconductor device and a method of fabricating the same.

2. Related Art

Semiconductor devices have been progressively highly integrated. As a result, various problems on processes occurred. For example, due to the reduction in a cell area, a photo etching process became increasingly difficult. In recent years, studies on high integration of the semiconductor devices such as a method of fabricating a multi-level cell (MLC) having a three-dimensional (3D) structure have been progressed. When cells are formed in multi layers, a diode may be used as a switching device.

The diode has received attention as a cell selection device in a multi-layered memory device. To stably drive cells, the diode has to be designed so that a large amount of current flows in a lower voltage under an “on” state, and current does not flow under an “off” state.

FIG. 1 is view illustrating a structure of a general diode.

As shown in FIG. 1, a diode 10 is a PIN diode and has a stacking structure of a first type semiconductor layer 12, a second type semiconductor layer 14, and a third type semiconductor layer 16.

For example, the first type semiconductor layer 12 may include an N type semiconductor layer and may be doped with phosphorus (P) and the third type semiconductor layer 16 may include a P type semiconductor layer and may be doped with boron (B).

Furthermore, after the third type semiconductor layer 16 is formed, a heat treatment process is performed to activate dopants.

However, ions doped in the first type semiconductor layer 12 and the third type semiconductor layer 16 are diffused into the second type semiconductor layer 14 in the heat treatment process. Referring to FIG. 1, first type ion is deeply diffused into the second type semiconductor layer 14 as indicated by a profile 81, and second type ion is deeply diffused into the second type semiconductor layer 14 as indicated by a profile A1.

Off-current characteristic of the diode tends to improve as the height of the second type semiconductor layer 14 is increased. When the dopants are deeply diffused from the first and third type semiconductor layers 12 and 16 into the second type semiconductor layer 14, the substantial height of the second type semiconductor layer 14 is reduced not to ensure diode characteristic.

Therefore, in the current PIN diode, the second type semiconductor layer 14 has to be formed to have a sufficient height, and thus, the total height H1 of the diode 10 may exceed 1700 Å.

A size in the semiconductor device is inevitably increased due to the height of the diode. When a diameter of the diode is appropriately reduced, the diode may collapse in a subsequent process.

### SUMMARY

In accordance with an embodiment of the present invention, the semiconductor device may include a first type semiconductor layer doped with an N type ion, a second type semiconductor layer formed over the first type semiconductor layer, and a silicon germanium (SiGe) layer doped with a P type ion formed over the second type semiconductor layer.

In accordance with another embodiment of the present invention, the method of fabricating a semiconductor device may include forming a first type semiconductor layer doped with an N type ion over a semiconductor substrate, forming a second type semiconductor layer over the first type semiconductor layer, forming a silicon germanium (SiGe) layer over the second type semiconductor layer, and doping a P type ion into the SiGe layer.

These and other features, aspects, and embodiments are described below in the section entitled “DETAILED DESCRIPTION”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a view illustrating a structure of a conventional diode;

FIG. 2 is a view illustrating a structure of a diode according to an exemplary embodiment of the inventive concept;

FIGS. 3 to 6 are cross-sectional views illustrating a method of fabricating a diode according to an exemplary embodiment of the inventive concept;

FIG. 7 is a view illustrating a structure of a diode according to another exemplary embodiment of the inventive concept;

FIG. 8 is a view illustrating a heat treatment method;

FIGS. 9 and 10 are graphs illustrating dopant diffusion information according to a heat treatment condition;

FIGS. 11 and 12 are views illustrating dopant diffusion information according to content of a semiconductor layer and a heat treatment condition; and

FIG. 13 is a graph illustrating voltage-current characteristic of a semiconductor device according to an exemplary embodiment of the inventive concept.

### DETAILED DESCRIPTION

Hereinafter, exemplary embodiment will be described in greater detail with reference to the accompanying drawings.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It should be readily understood that the meaning of “on” and “over” in the present disclosure should be interpreted in the broadest manner such that “on” not only means “directly on” something but also include the meaning of “on” something with an intermediate feature or a layer therebetween, and that “over” not only means the meaning of “over” something may also include the meaning it is “over” something with no intermediate feature or layer therebetween (i.e., directly on something).

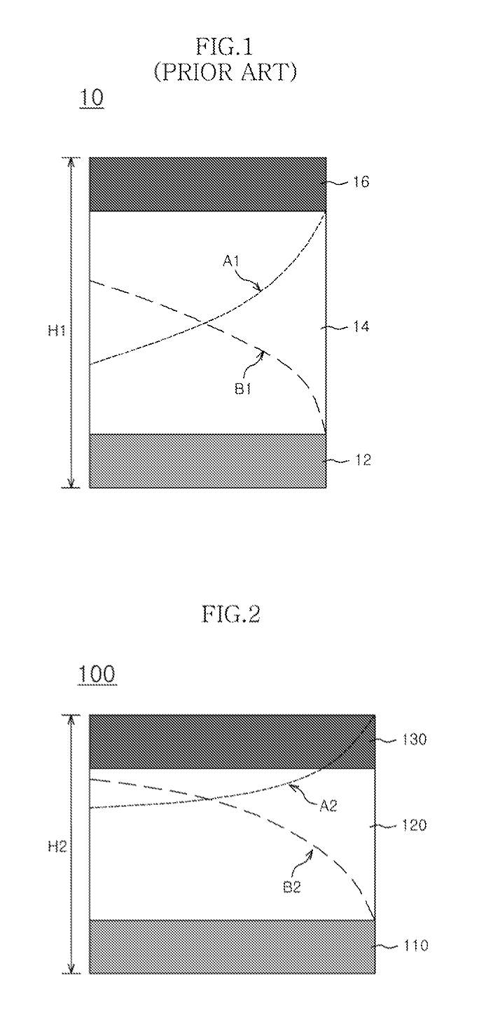

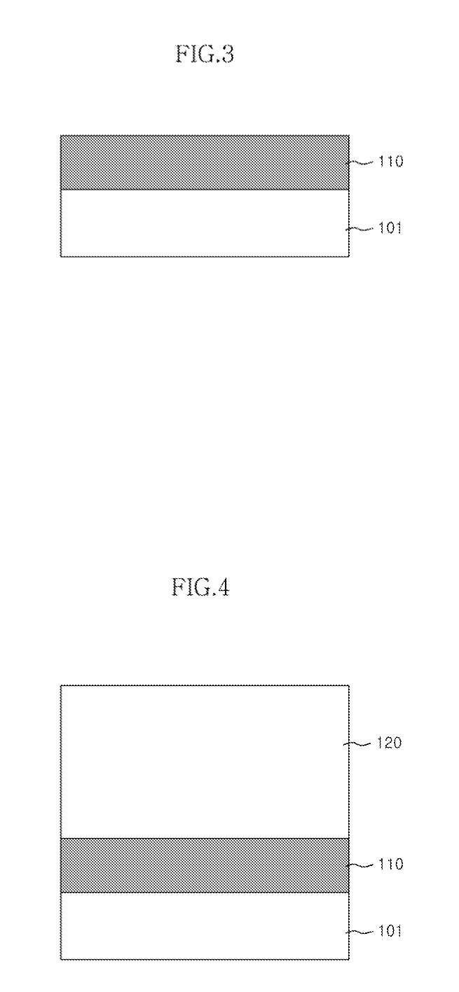

FIG. 2 is a view illustrating a structure of a diode according to an exemplary embodiment of the inventive concept.

Referring to FIG. 2, a diode 100 according to an exemplary embodiment includes a first type semiconductor layer 110, a second type semiconductor layer 120, and a third type semiconductor layer 130. Here, the first type semiconductor layer 110 may be an N type semiconductor layer and may be formed by doping a phosphorus (P) ion. The third type semiconductor layer 130 may be a P type semiconductor layer. In the exemplary embodiment, the third type semiconductor layer 130 may include a silicon germanium (SiGe) layer doped with a P type ion, for example, boron (B).

Germanium (Ge) is a material having a good dopant trapping property. In the exemplary embodiment, the third type semiconductor layer 130 may be formed of a SiGe layer and a P type ion is doped in the SiGe layer so that diffusion of the P type ion into the second type semiconductor layer 120 may be minimized (See diffusion profile A2). Therefore, even when a height of the second type semiconductor layer 120 is minimized, the height of the second type semiconductor layer 120 may be sufficiently ensured after the dopant diffusion so that the off current characteristic of the diode may be improved.

At this tire, a total height H2 of the diode 100 may be lowered to below 1000 Å. Therefore, vertical stability of the diode may be improved and a size of the semiconductor device may also be reduced.

A heat treatment process is performed after the first to third type semiconductor layers 110, 120, and 130 are formed. At this time, the heat treatment process is rapidly performed at a high temperature through a spike rapid thermal annealing (RTA) process, and thus, the dopant diffusion may further be suppressed.

The third type semiconductor layer 130 formed using silicon germanium (SiGe) may have an energy level lower than an energy level (1.17 eV) of a silicon layer. The energy level of the SiGe layer is lowered to 1.0 eV when content of Ge in the SiGe layer is 20%, while the energy level of the SiGe layer is lowered to 0.78 eV when content of Ge in the SiGe layer is increased to 50%.

As described above, when the energy level of the third type semiconductor layer is caused to be lowered using a boron (B)-doped SiGe layer, a threshold voltage among operation voltage characteristics is lowered and further a slope of an on current is increased. Thus, characteristics of the diode may further improve.

FIGS. 3 to 6 are cross-sectional views illustrating a method of fabricating a diode according to an exemplary embodiment of the inventive concept.

First, as shown in FIG. 3, a first type semiconductor layer 110 is formed on a semiconductor substrate 101 in which a bottom structure is formed. The first type semiconductor layer 110 may be formed, for example, by doping phosphorus (P) ions into an N type semiconductor layer. The P ions may be doped by in-situ so that a bottom doping concentration of the first type semiconductor layer 110 is in a range of above 1E19 atoms/cm³. At this time, when a metal layer is formed blow the first type semiconductor layer 110, the first type semiconductor layer forms an ohmic contact with the metal layer.

Alternatively, any one of dopants, which can represent N type ion characteristic other than the P ion, may be selected to form the first type semiconductor layer 110, and a doping concentration thereof may be controlled in a range of about 1E19 atoms/cm³ to 1E22 atoms/cm³.

In one exemplary embodiment, a cleaning process may be further performed on a surface of the semiconductor substrate 101 in which the bottom structure is formed before the first type semiconductor layer 110 is formed. The cleaning process for interface treatment may be performed to remove an oxide layer and other materials on surface by using any one of a wet method and a dry method, using all the wet method and the dry method, or using an in-situ method. When a metal layer is formed at an interface with the first type semiconductor layer 110, contamination-free metal is exposed through the cleaning process for interface treatment and thus a gas or a solution having good selectivity may be used to minimize metal loss. The cleaning process for interface treatment may be performed in a range of about a room temperature to 600° C.

As shown in FIG. 4, a second type semiconductor layer 120 is formed on the first type semiconductor layer 110. The second type semiconductor layer 120 may be an intrinsic semiconductor layer. As shown in FIG. 5, a third semiconductor layer 130, that is, a SiGe layer 130 is formed on the second type semiconductor layer 120.

In one exemplary embodiment, the SiGe layer 130 may be formed using amorphous silicon, or using a double structure of amorphous silicon containing Ge and polysilicon.

Furthermore, a carbon (C) concentration in forming the second type semiconductor layer 120 and a Ge concentration in forming the third type semiconductor layer 130 may be variably determined according to device characteristic. The C concentration may be in a rage of about 0.1% to 10 and the Ge concentration may be in a range of about 5% to 50%.

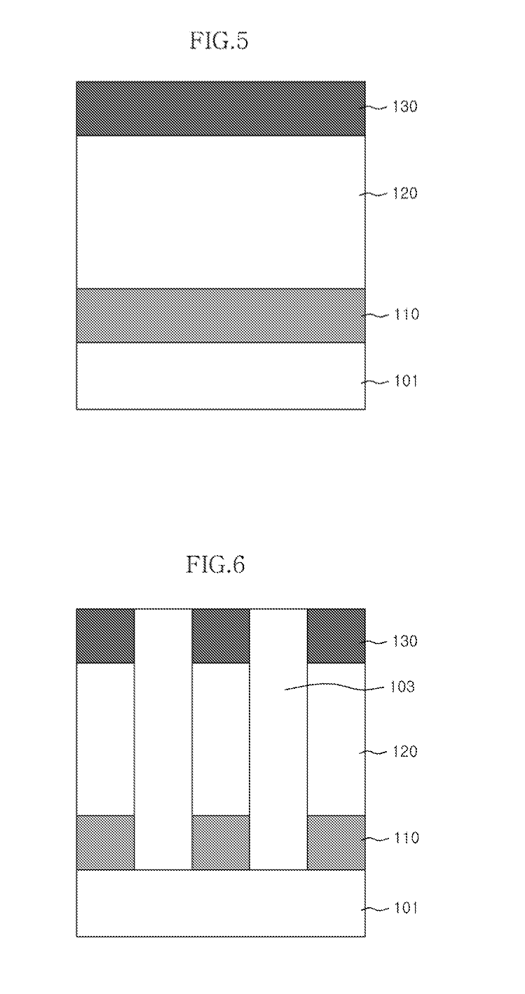

As shown in FIG. 6, the stacking structure of the first to third type semiconductor layers 110, 120, and 130 are patterned in a pillar shape and an insulating layer 103 is buried between the pillar shape structures. Next, a P type ion, for example, B ions are doped into the third type semiconductor layer 130. The insulating layer 103 may be selected from materials including oxide and may have a dual structure of nitride and oxide to more effectively block the dopant diffusion in a subsequent process.

The boron ions may be doped in an in-situ method. The boron ions may be doped so that a top concentration of the third type semiconductor layer 130 is about 1E19 atoms/cm³. At this time, when a metal layer is formed on the third semiconductor layer 130, the third type semiconductor layer forms an ohmic contact with the metal layer.

Any one of dopants which may represent P type ion characteristic other than the B ion may be selected to form the third type semiconductor layer 130, and the doping concentration may be controlled in a range of about 1E19 atoms/cm³ to 1E22 atoms/cm³.

After the P type ion is doped, a spike RTA process is performed to activate the N type ion and the P type ion.

The general RTA process is performed for a relatively long period of time while maintaining a desired temperature, while the spike RTA process is performed by instantaneously applying heat temperature greater than the temperature generally used in the general RTA process.

Therefore, the heat treatment is rapidly performed at the high temperature to suppress dopant diffusion and to cause crystallization to be performed simultaneously. In addition to suppress the dopant diffusion by introduction of SiGe, the dopant diffusion is more effectively suppressed by introduction of the spike RTA process.

Referring back to FIG. 2, it can be seen that there is almost no difference between the diffusion profile B2 of the N type ion and the diffusion profile in the N type ion in the general diode of FIG. 1, while the diffusion depth in the diffusion profile A2 of the P type ion is considerably lowered as compared to the diffusion profile A1 of the P type on in the general diode. The spike RTA process causes the height of the second type semiconductor layer 120 to be reduced, and thus, the total height H2 of the diode may be considerably reduced.

The first to third type semiconductor layers 110 to 130 may be formed using a deposition method such as low Pressure chemical vapor deposition (LPCVD), very low pressure CVD (VLPCVD), plasma-enhanced CVD (PECVD), ultrahigh vacuum CVD (UHV CVD), rapid thermal CVD (RTCVD), or atmosphere pressure CVD (APCVD). The deposition temperature may be controlled in a range of about 100 Å to 800 Å.

FIG. 7 is a view illustrating a structure of a diode according to another exemplary embodiment.

Referring to FIG. 7, a diode 100-1 according to the exemplary embodiment has a stacking structure of a first type semiconductor layer 110, a diffusion barrier layer 140, a second type semiconductor layer 120, and a third type semiconductor layer 130.

That is, the diode 100-1 according to the exemplary embodiment may include the diffusion barrier layer 140 formed between the first type semiconductor layer 110 and the second type semiconductor layer 120.

In one exemplary embodiment, the diffusion barrier layer 140 may be formed of a chemical oxide layer. The diffusion barrier layer 140 suppresses the N type ion doped in the first type semiconductor layer 110 from being diffused into the second type semiconductor layer 120, and thus, electric characteristic of the diode 100-1 may further be improved.

Comparison between the spike RTA that is performed after forming the third type semiconductor layer 130 and doping the P type ion into the third semiconductor layer in the exemplary embodiment described above and the general RTA will be made later.

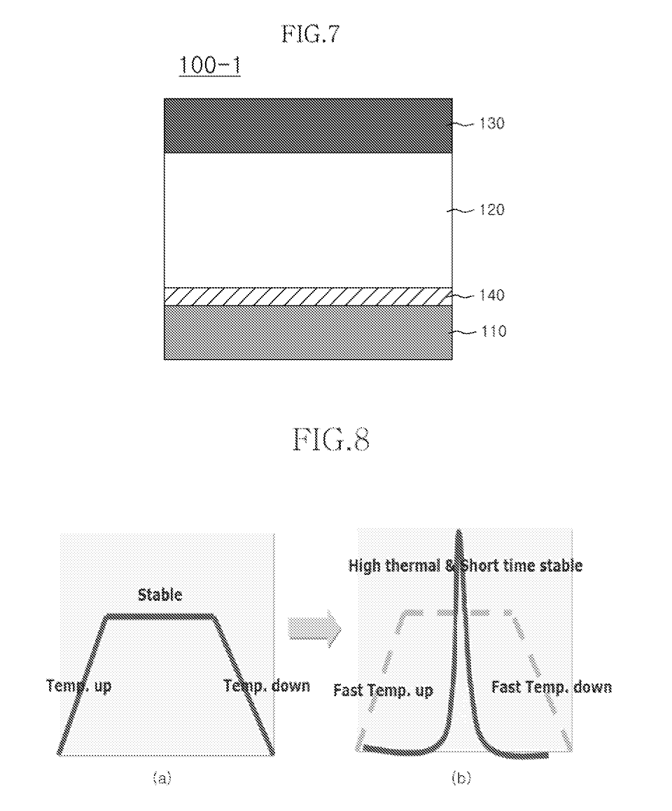

FIG. 8 is a view illustrating a heat treatment method.

FIG. 8(a) illustrates a heating profile in the general RTA process. The heating temperature gradually rises, is maintained for a relatively long period of time at a high temperature, and gradually drops down.

Meanwhile, in the spike RTA process, as shown in FIG. 8(b), the heating temperature rapidly rises, is maintained for a relatively short period of time at a high temperature, and then rapidly drops down.

In the exemplary embodiment, the dopant is activated, and simultaneously the dopant diffusion is effectively prevented by rapidly applying a high temperature using the spike RTA.

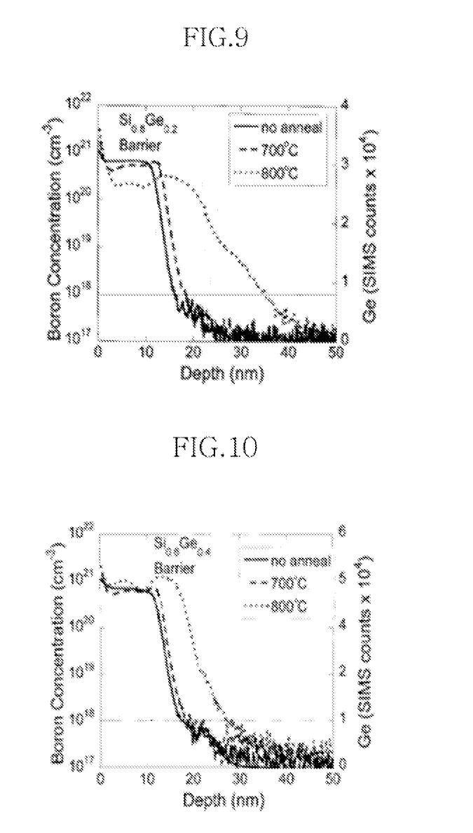

FIGS. 9 and 10 are graphs illustrating dopant diffusion information according to a heat treatment condition.

First, FIG. 9 illustrates B concentrations in the second type semiconductor layer 120 when a heat treatment process is not performed on a SiGe layer, that is, Si_{0.8}Ge_{0.2} and when a heat treatment process is performed on the SiGe layer (Si_{0.8}Ge_{0.2}) at temperatures of 700° C. and 800° C.

The B concentration in the second type semiconductor layer may be lowered as the temperature in the heat treatment process becomes high, and thus, the B diffusion is prevented.

FIG. 10 shows B concentrations in the second type semiconductor layer 120 when a heat treatment process is not performed on a SiGe, layer, that is, S_{0.6}Ge_{0.4} and when a heat treatment process is performed on the SiGe layer (Si_{0.6}Ge_{0.4}) at temperatures of 700° C. and 800° C.

The B concentration in the second type semiconductor layer 120 can be seen according to the heat treatment condition when the Ge content in the SiGe layer is increased compared to FIG. 9.

As the Ge content is increased, the diffusion degree into the second type semiconductor layer 120 may be remarkably reduced compared to FIG. 9.

According to FIGS. 9 and 10, the dopant diffusion may be suppressed as the heat treatment process is performed at the high temperature. Furthermore, the dopant diffusion is effectively reduced as the Ge content in the SiGe layer is increased.

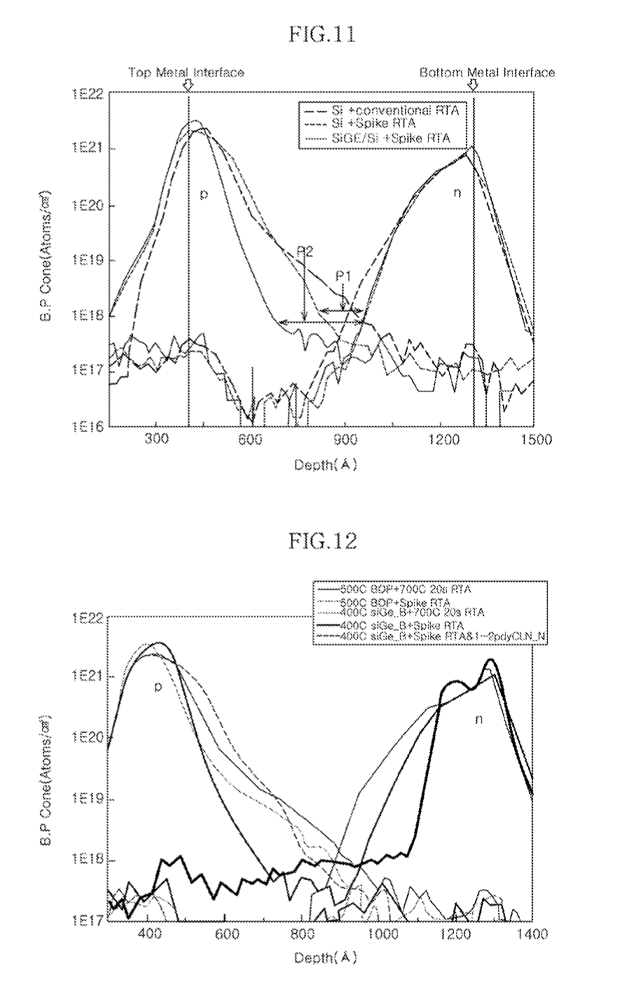

FIGS. 11 and 12 are views illustrating dopant diffusion information according to content of a semiconductor layer and heat treatment condition.

First, referring to FIG. 11, the dopant diffusion tendency into the second semiconductor layer can be seen in following cases: (1) where a silicon layer is used as the third type semiconductor layer 130 and the heat treatment is performed using a general RTA process, (2) where a silicon layer is used as the third type semiconductor layer 130 and the heat treatment is performed using a spike RTA, and (3) where a stacking structure of a SiGe layer and a Si layer is used as the third type semiconductor layer 130 and the heat treatment is performed using a spike RTA.

The dopant concentration may be controlled to be high at an interface between the first type semiconductor layer 110 and an underlying layer (for example, a metal layer) and at an interface between the third type semiconductor layer 130 and an overlying layer (for example, a metal layer), and thus, the ohmic contacts are formed at the interfaces.

Furthermore, in comparisons of the concentrations of the dopants diffused into the second type semiconductor layer 120 between the cases (1), (2), and (3), the dopant diffusion may be remarkably reduced when the SiGe layer and the spike RTA are applied.

That is, referring to FIG. 11, a height P1 of the second semiconductor layer 120 is as low as about 140 Å when the spike RTA is performed using the Si layer as the third type semiconductor layer.

On the other hand, referring to FIG. 11, a height P2 of the second semiconductor layer 120 is substantially increased, that is, to about 280 Å when the SiGe layer is used as the third type semiconductor layer 130 and the spike RTA is performed.

Thus, it can be seen that the height of the diode is lowered when the SiGe layer and the spike RTA are applied.

FIG. 12 illustrates diffusion degrees of B and P according to a heat treatment condition in following cases: (1) where the B-doped polysilicon layer BDP is used as the third type semiconductor layer; and (2) where a B-doped SiGe layer is used as the third semiconductor layer.

It can be seen that ion diffusion is suppressed when a spike RTA process is performed as compared to the general RTA process. Furthermore, B diffusion may be remarkably reduced when B ions are doped in the SiGe layer as compared when B ions are doped in the polysilicon layer.

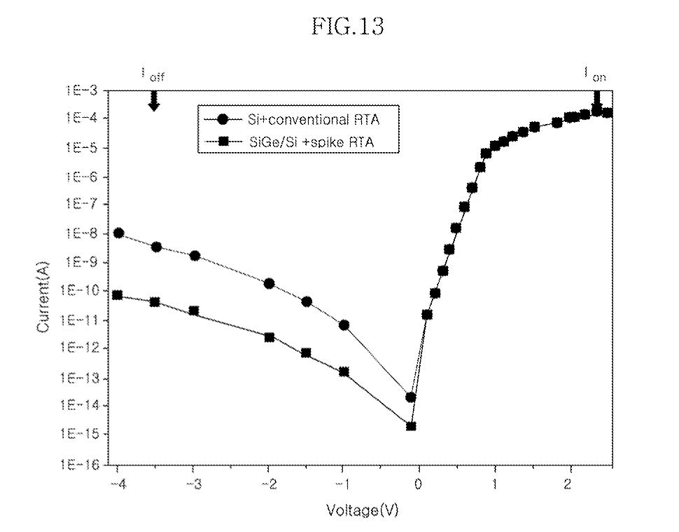

FIG. 13 is a graph illustrating current-voltage characteristic of a semiconductor device according to an exemplary embodiment of the inventive concept.

As described above, the off current characteristic of the diode becomes desirable as the height of the second type semiconductor layer is increased.

FIG. 13 shows the off current characteristic and on current characteristic in following cases: (1) where a Si layer is used as the third type semiconductor layer and heat treatment is performed using a conventional RTA process as in the general PIN diode; and (2) where a SiGe layer is used as the third type semiconductor layer and dopants are activated in a spike RTA process in the exemplary embodiment.

According to FIG. 13, the leakage current may be remarkably reduced in the off state of the diode when the diode structure of the exemplary embodiment is applied. That is, electric characteristics of the diode may be improved.

The above embodiment of the present invention is illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

What is claimed is:

1. A semiconductor device, comprising:
a first type semiconductor layer doped with an N type ion;
a second type semiconductor layer formed over the first type semiconductor layer; and
a silicon germanium (SiGe) layer doped with a P type ion formed over the second type semiconductor layer.

2. The semiconductor device of claim 1, wherein the first type semiconductor layer and the SiGe layer are crystallized by a spike rapid thermal annealing (RTA) process.

3. The semiconductor device of claim 2, further comprising a diffusion barrier layer interposed between the first type semiconductor layer and the second type semiconductor layer.

4. The semiconductor device of claim 1, wherein Ge content of the SiGe layer is in a range of 5% to 50%.

5. The semiconductor device of claim 1, wherein a top doping concentration of the P type ion in the SiGe layer is in a range of 1E19 atoms/cm³ to 1E22 atoms/cm³.

6. The semiconductor device of claim 1, wherein a bottom doping concentration of the N type ion in the first type semiconductor layer is in a range of 1E19 atoms/cm³ to 1E22 atoms/cm³.

7. The semiconductor device of claim 1, wherein the second type semiconductor layer is an intrinsic semiconductor layer.

8. The semiconductor device of claim 1, further comprising a diffusion barrier layer interposed between the first type semiconductor layer and the second type semiconductor layer.

9. A method of fabricating a semiconductor device, the method comprising:
forming a first type semiconductor layer doped with an N type ion over a semiconductor substrate;
forming a second type semiconductor layer over the first type semiconductor layer;
forming a silicon germanium (SiGe) layer over the second type semiconductor layer; and
doping a P type ion into the SiGe layer.

10. The method of claim 9, further comprising performing a spike rapid thermal annealing (RTA) process after doping the P type ion into the SiGe layer.

11. The method of claim 10, further comprising forming a diffusion barrier layer over the first type semiconductor layer before forming the second type semiconductor layer.

12. The method of claim 9, wherein Ge content in the SiGe layer is in a range of 5% to 50%.

13. The method of claim 9, wherein a top doping concentration of the P type ion in the SiGe layer is in a range of 1E19 atoms/cm³ to 1E22 atoms/cm³.

14. The method of claim 9, wherein a bottom doping concentration of the N type ion in the first type semiconductor layer is in a range of 1E19 atoms/cm³ to 1E22 atoms/cm³.

15. The method of claim 9, wherein the second type semiconductor layer is an intrinsic semiconductor layer.

16. The method of claim 9, further comprising forming a diffusion barrier layer between the first type semiconductor layer and the second type semiconductor layer.
